(19) United States
(12) Patent Application Publication
(10) Pub. No.: US 2025/0079114 A1
(43) Pub. Date: Mar. 6, 2025

(54) ION PROBE WITH COUPLING TO PLASMA

(71) Applicant: APPLIED MATERIALS, INC., Santa Clara, CA (US)

(72) Inventors: ANDREI KHOMENKO, Sunnyvale, CA (US); LEONID DORF, San Jose, CA (US); EVGENY KAMENETSKIY, San Jose, CA (US); VIACHESLAV PLOTNIKOV, San Jose, CA (US); RAJINDER DHINDSA, Pleasanton, CA (US)

(21) Appl. No.: 18/793,576

(22) Filed: Aug. 2, 2024

Related U.S. Application Data
(60) Provisional application No. 63/536,600, filed on Sep. 5, 2023.

(51) Int. Cl. H01J 37/08; H01J 37/32

(52) U.S. Cl. CPC H01J 37/08; H01J 37/32963

(57) ABSTRACT

Embodiments include a plasma processing apparatus including a chamber with an inner chamber wall. A workpiece support is within the inner chamber wall, the workpiece support for supporting a workpiece in a processing region of the chamber. An ion probe extends through the chamber and inner chamber wall and into a plasma region above the workpiece.

### CROSS-REFERENCE TO RELATED APPLICATIONS

This application claims the benefit of U.S. Provisional Application No. 63/536,600, filed on Sep. 5, 2023, the entire contents of which are hereby incorporated by reference herein.

### BACKGROUND

### 1) Field

Embodiments relate to the field of plasma processing and, in particular, to plasma processing chambers including an ion probe.

### 2) Description of Related Art

Plasma processing is used extensively in the manufacture of many different technologies, such as those in the semiconductor industry, display technologies, microelectromechanical systems (MEMS), and the like. Currently, radio frequency (RF) generated plasmas are most often used.

Reliably producing high aspect ratio features is one of the key technology challenges for the next generation of very large scale integration (VLSI) and ultra large scale integration (ULSI) of semiconductor devices. One method of forming high aspect ratio features uses a plasma assisted etching process, such as a reactive ion etch (RIE) plasma process, to form high aspect ratio openings in a material layer, such as a dielectric layer, of a substrate. In a typical RIE plasma process, a plasma is formed in an RIE processing chamber and ions from the plasma are accelerated towards a surface of a substrate to form openings in a material layer disposed beneath a mask layer formed on the surface of the substrate.

A typical Reactive Ion Etch (RIE) plasma processing chamber includes a radio frequency (RF) bias generator, which supplies an RF voltage to a “power electrode” (e.g., a biasing electrode), such as a metal plate positioned adjacent to an “electrostatic chuck” (ESC) assembly, more commonly referred to as the “cathode”. The power electrode can be capacitively coupled to the plasma of a processing system through a thick layer of dielectric material (e.g., ceramic material), which is a part of the ESC assembly. In a capacitively coupled gas discharge, the plasma is created by using a radio frequency (RF) generator that is coupled to an RF electrode through an RF matching network (“RF match”) that tunes the apparent load to 50Ω to minimize the reflected power and maximize the power delivery efficiency. The application of RF voltage to the power electrode causes an electron-repelling plasma sheath (also referred to as the “cathode sheath”) to form over a processing surface of a substrate that is positioned on a substrate supporting surface of the ESC assembly during processing. The non-linear, diode-like nature of the plasma sheath results in rectification of the applied RF field, such that a direct-current (DC) voltage drop, or “self-bias”, appears between the substrate and the plasma, making the substrate potential negative with respect to the plasma potential. This voltage drop determines the average energy of the plasma ions accelerated towards the substrate, and thus etch anisotropy. More specifically, ion directionality, the feature profile, and etch selectivity to the mask and the stop-layer are controlled by the Ion Energy Distribution Function (IEDF). In plasmas with RF bias, the IEDF typically has two non-discrete peaks, one at a low energy and one at a high energy, and an ion population that has a range of energies that extend between the two peaks. The presence of the ion population in-between the two peaks of the IEDF is reflective of the fact that the voltage drop between the substrate and the plasma oscillates at the RF bias frequency. When a lower frequency RF bias generator is used to achieve higher self-bias voltages, the difference in energy between these two peaks can be significant; and because the etch profile due to the ions at low energy peak is more isotropic, this could potentially lead to bowing of the etched feature walls. Compared to the high-energy ions, the low-energy ions are less effective at reaching the corners at the bottom of the etched feature (e.g., due to the charging effect), but cause less sputtering of the mask material. This is important in high aspect ratio etch applications, such as hard-mask opening or dielectric mold etch. As feature sizes continue to diminish and the aspect ratio increases, while feature profile control requirements become more stringent, it becomes more desirable to have a well-controlled IEDF at the substrate surface during processing.

Other conventional plasma processes and processing chamber designs have also found that delivering multiple different RF frequencies to one or more of the electrodes in a plasma processing chamber can be used to control various plasma properties, such as plasma density, ion energy, and/or plasma chemistry. However, it has been found that the delivery of multiple conventional sinusoidal waveforms from two or more RF sources, which are each configured to provide different RF frequencies, is unable to adequately or desirably control the sheath properties and can lead to undesirable arcing problems. Moreover, due to direct or capacitive coupling between the RF sources during processing, each RF source may induce an RF current that is provided to the output of the other connected RF source(s) (e.g., often referred to as the “cross-talk”), resulting in the power being diverted away from the intended load (plasma), as well as a possibly causing damage to each of the RF sources.

Accordingly, there is a need in the art for novel, robust and reliable plasma processing and biasing methods that enable maintaining a nearly constant sheath voltage, and thus create a desirable and repeatable IEDF at the surface of the substrate to enable a precise control over the shape of IEDF and, in some cases, the etch profile of the features formed in the surface of the substrate.

To that end, pulsed voltage technology (VT) involves a biasing scheme that is configured to provide a radio frequency (RF) generated RF waveform from an RF generator to one or more electrodes within a processing chamber and a pulsed-voltage (PV) waveform delivered from one or more pulsed-voltage (PV) generators to the one or more electrodes within the processing chamber. In general, the generated RF waveform is configured to establish and maintain a plasma within the processing chamber, and the delivered PV waveform(s) are configured to establish a nearly constant sheath voltage across the surface of a substrate and thus create a desirable ion energy distribution function (IEDF) at the surface of the substrate during one or more plasma processing steps performed within the processing chamber. The plasma process(es) disclosed herein can be used to control the shape of IEDF and thus the interaction of the plasma with a surface of a substrate during processing. In some configurations, the plasma process(es) disclosed herein are used to control the profile of features formed in the surface of the substrate during processing. In some embodiments, the pulsed voltage waveform is established by a PV generator that is electrically coupled to a biasing electrode disposed within a substrate support assembly disposed within a plasma processing chamber.

### SUMMARY

Embodiments include an ion probe for capacitively coupling to a bulk plasma in a plasma region of a plasma processing apparatus that includes an outer alumina tube surrounding an inner aluminum tube, and an aluminum wire extending through a portion of a center of the inner aluminum tube, the aluminum wire held by crimps.

According to an embodiment, a plasma processing apparatus includes a chamber with an inner chamber wall. A workpiece support is within the inner chamber wall, the workpiece support for supporting a workpiece in a processing region of the chamber. An ion probe extends through the chamber and inner chamber wall and into a plasma region above the workpiece

In an additional embodiment, a method for monitoring a plasma parameter includes providing an ion probe extending through a chamber and inner chamber wall and into a plasma region of a plasma processing apparatus, and measuring ion density, or ion energy distribution, or both ion density and ion energy distribution of a pulsed plasma in a plasma processing apparatus using the ion probe.

The above summary does not include an exhaustive list of all embodiments. It is contemplated that all systems and methods are included that can be practiced from all suitable combinations of the various embodiments summarized above, as well as those disclosed in the Detailed Description below and particularly pointed out in the claims filed with the application. Such combinations have particular advantages not specifically recited in the above summary.

### BRIEF DESCRIPTION OF THE DRAWINGS

FIG. 1 is a simplified schematic diagram of a biasing scheme that can be used with a plasma process chamber including an ion probe, in accordance with an embodiment of the present disclosure.

FIG. 2 illustrates an example of negative pulsed voltage (PV) waveforms established at the biasing electrode and substrate, in accordance with an embodiment of the present disclosure.

FIG. 3 illustrates a plan view of an ion probe inserted into a plasma processing region of a plasma processing chamber, in accordance with an embodiment of the present disclosure.

FIGS. 4A-4C illustrate cross-sectional views of various arrangements including an ion probe inserted into a plasma processing region of a plasma processing chamber, in accordance with an embodiment of the present disclosure.

FIGS. 4D-4E illustrate cross-sectional view of ion probes for use in a plasma processing region of a plasma processing chamber, in accordance with an embodiment of the present disclosure.

FIG. 5 is a flowchart representing various operations in a method of using an ion probe to collect plasma measurements, in accordance with an embodiment of the present disclosure.

### DETAILED DESCRIPTION

A plasma processing chamber including an ion probe is described in accordance with various embodiments. In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

Embodiments include an ion current probe with significant capacitive coupling to plasma.

In accordance with one or more embodiments of the present disclosure, a coupling capacitor to bulk plasma inside a probe body is described. In one embodiment, the capacitor includes an electrode (such as an aluminum tube inside a probe body), an inter-electrode gap (such as an alumina probe body and probe body sheath), and the other electrode which is the bulk plasma. In one embodiment, this coupling is much larger than the Ground parasitic coupling.

To provide context, in conventional ion current probe systems, the probe tip does not follow the plasma potential during time-cycle, and thus there is no constant potential difference between the probe tip and surrounding bulk plasma. The result can be probe tip sheath expansions and collapses over a time-cycle, fickle ion collection area and thus non-reliable ion current readout. In an embodiment, a probe tip is made to follow the bulk plasma potential with stable voltage difference between them.

To provide further context, plasma probes have not been described for plasmas with large jumps in plasma potential. In modern plasma reactors with pulse plasmas, the driving field, electric or magnetic, enhances and extinguishes the plasma periodically, resulting in a time-varying plasma parameters: plasma potential, ion density and electron temperature. The plasma potential can differ significantly over time-cycle, with difference of several hundreds of volts.

Advantages for implementing embodiments described herein can include that the described ion current probes can precisely measure major plasma parameter-ion density, in pulsed plasmas. The quality and the uniformity of the plasma play a crucial role in determining the properties and characteristics of the material etched or deposited. For example, in plasma etch, if the plasma is not uniform across the wafer, some area may be over-etched or under-etched, which can lead to variations in the feature dimensions. This can result in non-functional or unreliable devices, leading to low yield. Embodiments can be implemented to address and remedy such issues.

Embodiments can be implemented to include a probe that provides a coupling capacitor inside a probe body. In one embodiment, a probe tip has a relatively large ion collection area. In one embodiment, a probe tip resistor is included. In one embodiment, a vacuum feedthrough is included with low parasitic coupling to ground. In one embodiment, a probe RF filter is included. In one embodiment, a probe pulse-voltage filter is included. In one embodiment, a probe bias supply filter is included. In one embodiment, a probe current shunt is included.

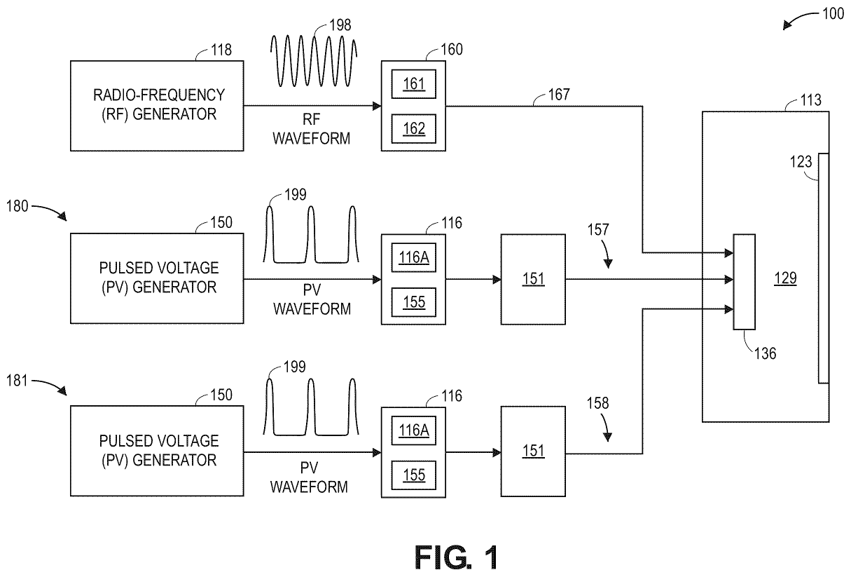

It is to be appreciated that ion probes described herein can be implemented for use with a pulsed plasma in a variety of arrangements. As an exemplary implementation, regarding plasma processing biasing schemes and processes, FIG. 1 is a simplified schematic diagram of a biasing scheme that can be used with a plasma process chamber including an ion probe, in accordance with an embodiment of the present disclosure.

As shown in FIG. 1, an RF generator 118 and PV waveform generators 150 are configured to deliver an RF waveform and pulsed-voltage waveforms, respectively, to one or more electrodes disposed within the chamber body 113 of the processing chamber 100. In one embodiment, the RF generator 118 and PV waveform generators 150 are configured to simultaneously deliver an RF waveform and pulsed-voltage waveform(s) to one or more electrodes disposed within the substrate support assembly 136. In one non-limiting example, as discussed above, the RF generator 118 and a PV waveform generator 150 are configured to deliver an RF waveform and pulsed-voltage waveform to the support base 107 and biasing electrode 104, respectively, which are both disposed in the substrate support assembly 136. In another example, the RF generator 118, a first PV waveform generator 150 and a second PV waveform generator 150 are configured to deliver an RF waveform, a first pulsed-voltage waveform and a second pulsed-voltage waveform to the support base 107, the biasing electrode 104 and the edge control electrode 115, respectively, which are all disposed in the substrate support assembly 136.

As illustrated in FIG. 1, the RF generator 118 is configured to provide a sinusoidal RF waveform to the one or more electrodes disposed in the chamber body 113 by delivering the RF signal, which includes the sinusoidal RF waveform 198, through the plasma generator assembly 160, which includes the RF matching circuit 161 and the first filter assembly 162. Additionally, each of the PV waveform generators 150 are configured to provide a PV waveform, which typically includes a series of voltage pulses (e.g., nanosecond voltage pulses), to the one or more electrodes disposed in the chamber body 113 by establishing a PV waveform 199 at the biasing electrode 104 through the second filter assembly 151. The components within the chucking module 116 can be optionally positioned between each PV waveform generator 150 and the second filter assembly 151.

To provide further context, regarding PVT uniformity, in a dual-frequency capacitively coupled plasma (CCP) with disparate frequencies, the low frequency (LF) voltage usually has a strong influence on the ion energy distribution function (IEDF) but contributes less to plasma generation. It is well-known that rectangular LF voltage waveform with a small positive period yields a narrow, nearly monoenergetic IEDF. When the LF voltage is low, the peak in plasma density is at the chamber center due to ample diffusion at the low pressure considered (20 mTorr) and higher losses to the chamber walls. As the LF voltage is increased, the sheath gets thicker at the powered electrode and charged species densities decrease for a constant 40 MHz voltage. The plasma profile, however, evolves differently for the two LF voltage waveforms. With sinusoidal LF voltage, the plasma spreads out between the electrodes. On the other hand, with rectangular LF voltage waveform, the plasma splits into two regions: a density peak at the chamber center and another peak near the electrode edge. This double-peaked density profile with a rectangular wave can be attributed to the location and timing of plasma generation. 40 MHz produces plasma most efficiently when the LF rectangular wave is positive and the sheath at the powered electrode is thin (frequency coupling). This plasma is produced uniformly between the electrodes, but only for a short period. When the LF voltage becomes negative, the sheath expands at the powered electrode and the plasma is produced near the electrode edge where the sheath is thinner and the electric field is stronger.

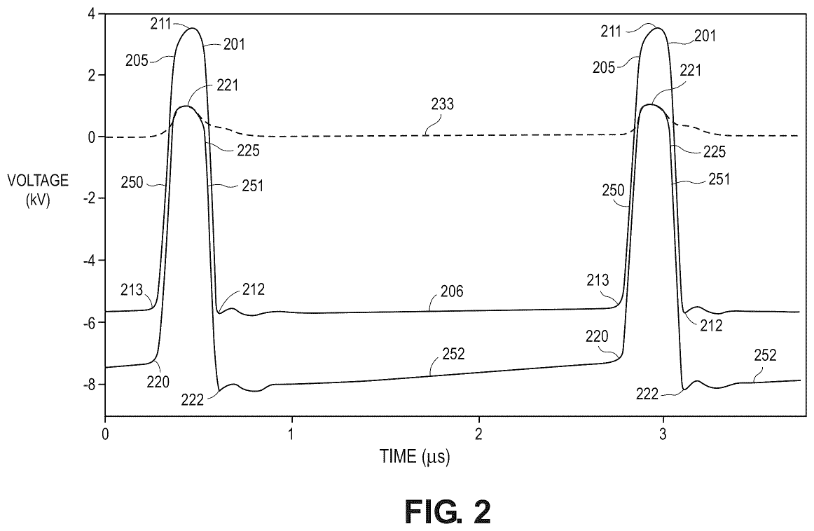

FIG. 2 illustrates a negative-pulse biasing scheme type of PV waveform that can be established at the biasing electrode 104 and/or edge control electrode 115 by use of a PV waveform generator 150 within a PV source assembly. In some embodiments, the PV waveform illustrated in FIG. 2 is separately established at the biasing electrode 104 and edge control electrode 115 by use of the PV waveform generator 150 of a first PV source assembly and the PV waveform generator 150 of a second PV source assembly, respectively. In some embodiments, the multiphase negative pulse waveforms 201 includes a series of repeating cycles, such that a waveform within each cycle has a first portion that occurs during a first time interval and a second portion that occurs during a second time interval. The multiphase negative pulse waveforms 201 can also include a positive voltage-pulse that is only present during at least a portion of the first time interval, and the pulsed voltage waveform is substantially constant during at least a portion of the second time interval. An output of the PV waveform generator 150 is connected to a negative voltage supply for at least a portion of the second time interval.

The substrate PV waveform 225, as shown in FIG. 2, is a series of PV waveforms established at the substrate due to the established PV waveform formed at the biasing electrode 104 or edge control electrode 115 by a PV waveform generator 150. The substrate PV waveform 225 is established at the surface of a substrate during processing, and includes a sheath collapse and ESC recharging phase 250 (or for simplicity of discussion the sheath collapse phase 250) that extends between point 220 and point 221 of the illustrative substrate PV waveform 225, a sheath formation phase 251 that extends between point 221 and point 222, and an ion current phase 252 that extends between point 222 and back to the start at point 220 of the next sequentially established pulse voltage waveform. The plasma potential curve 233, as shown in FIG. 2, illustrates the local plasma potential during the delivery of the negative pulse waveforms 401 that are established at the biasing electrode 104 and/or edge control electrode 115 by use of one or more PV waveform generators 150.

In some embodiments, during processing in the processing chamber 100, a multiphase negative pulse waveform 201 is formed when a PV waveform generator 150 supplies and controls the delivery of a negative voltage during two of the phases of the established multiphase negative pulse waveform 201, such as the portions of the PV waveform that trend in a negative direction and/or are maintained at a negative voltage level (e.g., ion current phase). For example, these negative voltage-containing portions of the negative pulse waveform 201 would, by analogy, relate to the sheath formation phase 251 and the ion current phase 252 illustrated in FIG. 2 for the substrate PV waveform 225. In this case, for a multiphase negative pulse waveform 201, the delivery of a negative voltage from a PV waveform generator 150 occurs during the second phase 206, which extends from or between the point 211 (i.e., peak of multiphase negative pulse waveform 201) and the start of the sheath collapse phase 250 of the substrate PV waveform that coincides with point 213, as shown in FIG. 2. In some embodiments, during the ion current phase 252, which coincides with the portion of the established multiphase negative pulse waveform 201 that is between points 212 and 213, the PV waveform generator 150 is configured to provide a constant negative voltage (e.g., VOUT). Due to, for example, the ion current (Ii) depositing positive charge on the substrate surface during the ion current phase 252, the voltage at the substrate surface will increase over time, as seen by the positive slope of the line between points 222 and 220 (FIG. 2). The voltage increase over time at the substrate surface will reduce the sheath voltage and result in a spread of the ion energy. Therefore, it may be desirable to control and set at least the PV waveform frequency to minimize the effects of the reduction in the sheath voltage and spread of the ion energy.

In an embodiment, a plasma probe for analyzing plasma characteristics is disclosed, e.g., for including in a chamber such as described above or in any suitable chamber for measuring a pulsed plasma formed therein. It is to be appreciated that plasma processing is a critical operation in the semiconductor industry, where techniques such as dry plasma etch, ion implementation and deposition are widely used. The quality and the uniformity of the plasma play a crucial role in determining the properties and characteristics of the material etched or deposited. In plasma etch, if the plasma is not uniform across the wafer, some area may be over-etched or under-etched, which can lead to variations in the feature dimensions. This can result in non-functional or unreliable devices, leading to a lower yield and higher manufacturing cost. Thus, it can be important to ensure a uniform plasma across the entire wafer to achieve a high yield and consistent device performance.

To achieve the desired performance and characteristics off all chips across a wafer-from center to edge, a uniform plasma across may be required across a wafer from center to edge. There are many “tuning knobs” in modern plasma reactors, by which plasma radial profile could be adjusted, but mostly those “knobs” crosstalk to each other and do not have straightforward impact on common plasma uniformity issues, for instance, plasma density center peak high. To understand a “tuning knob” effect, researchers could verify “on wafer” parameters after plasma treatment, but this approach can be highly time and resources consuming, and cannot be done in “real time.” In an embodiment, plasma probe measurements are implemented to provide “real time” plasma diagnostics.

It is to be appreciated that there are several types of plasma probes including Langmuir probes, radical probes, ion current probes. An ion current probe is a type of Langmuir probe used to measure plasma parameters, particularly the ion density and the ion energy distribution. It is referred to as an “ion current” probe because it measures the current of the ions flowing to the probe tip. A voltage is applied between the probe and the surrounding plasma. This voltage creates an electric field that accelerates the ions towards the probe tip. In an embodiment, these probes are particularly useful in measuring ion properties in plasmas, which is important for understanding the interaction between the ions and material under treatment.

To provide further context, in modern plasma reactors with multi-frequency RF plasmas, pulse-DC plasmas, and pulse plasmas, the driving field, electric or magnetic, enhances and extinguishes the plasma periodically, resulting in a time-varying plasma parameters: plasma potential, ion density and electron temperature. The plasma potential can differ significantly over time-cycle, with differences of several hundred volts. In conventional ion current probe systems, the probe tip does not follow the plasma potential during time-cycle, and thus there is no constant potential difference between the probe tip and surrounding bulk plasma.

In accordance with one or more embodiments of the present disclose, an ion current plasma probe with a tip that is significantly capacitively coupled to the bulk plasma is implemented for pulsed plasma measurements. In common probe systems, the tip-to-plasma capacitance is determined by the probe tip area, its sheath thickness and sheath expansion, and has a value of several pF. This capacitance is usually smaller than the stray capacitance to ground, causing probe tip be more coupled to ground than to bulk plasma. In an embodiment, an ion current probe is used which has a probe tip decoupled from ground and instead coupled to the bulk plasma.

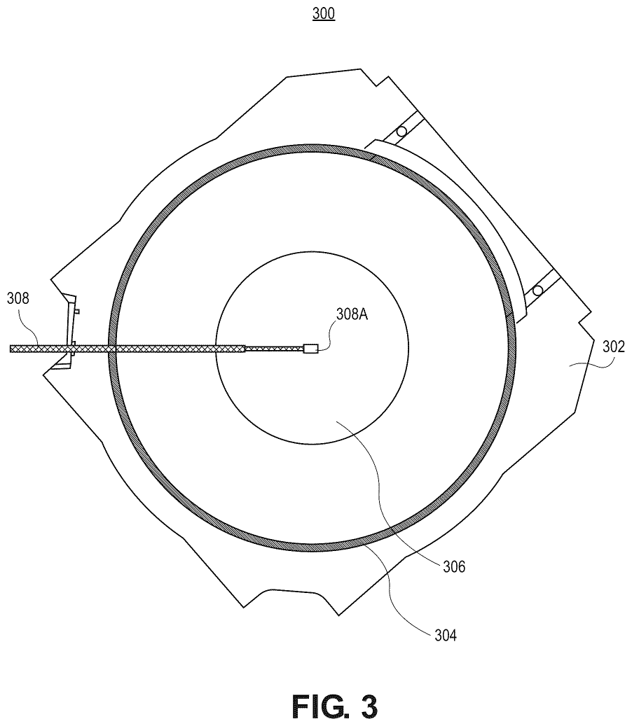

As an exemplary implementation of an ion probe in a plasma chamber, FIG. 3 illustrates a plan view of an ion probe inserted into a plasma processing region of a plasma processing chamber, in accordance with an embodiment of the present disclosure.

Referring to FIG. 3, a plasma processing apparatus 300 includes a chamber body 302 with an inner chamber wall 304. A workpiece support 306 is within the inner chamber wall 304 and is for supporting a workpiece in a processing region of the plasma processing apparatus 300. An ion probe 308 extends through the chamber body 302 and the inner chamber wall 304 and into a plasma region above the workpiece support 306. The ion probe 308 has a probe tip 308A which, in one embodiment, is suspended over a center of the workpiece 306. In some embodiments, the ion probe 308 can be moved to provide the probe tip 308A over a variety of different locations within the inner chamber wall and over the workpiece support 306.

In an embodiment, the ion probe 308 is configured to measure ion density, or ion energy distribution, or both ion density and ion energy distribution. In an embodiment, the ion probe 308 is an ion current plasma probe with the probe tip 308A capacitively coupled to a bulk plasma in the plasma region for pulsed plasma measurements.

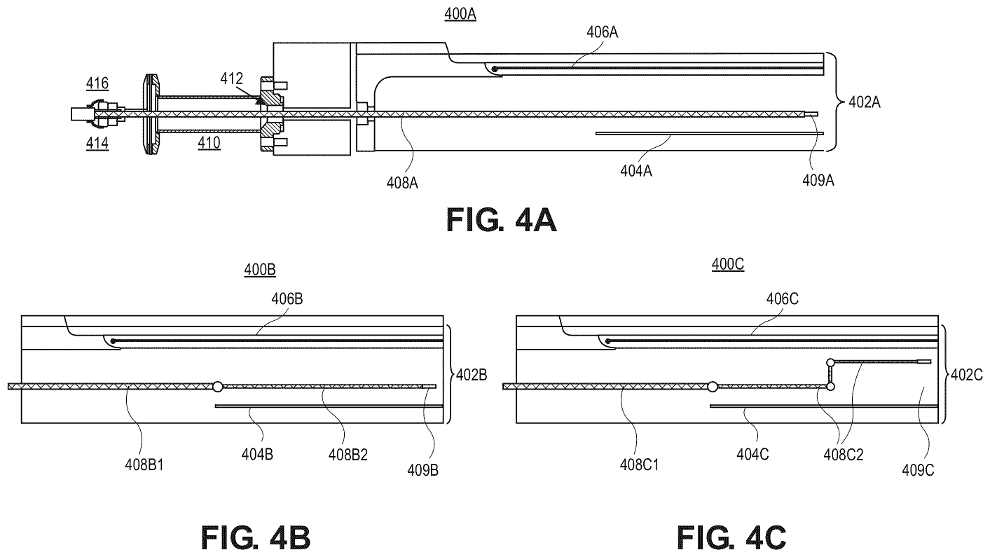

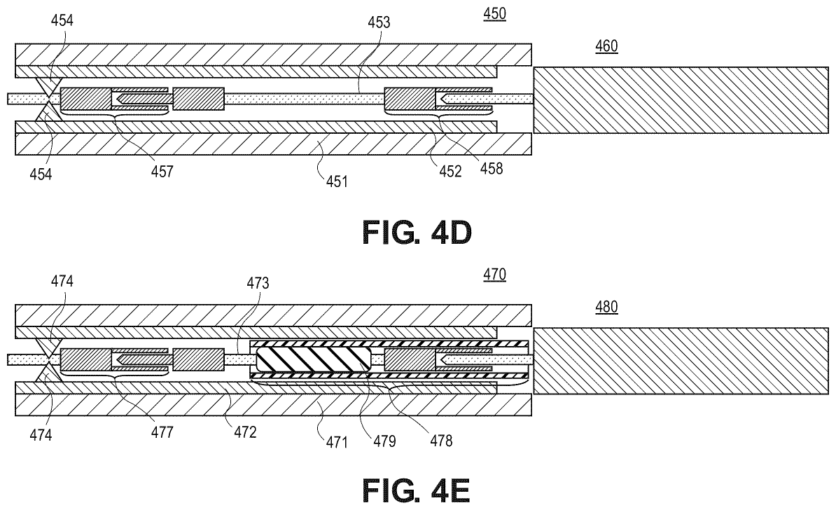

As additional exemplary implementations of an ion probe in a plasma chamber, FIGS. 4A-4C illustrate cross-sectional views of various arrangements including an ion probe inserted into a plasma processing region of a plasma processing chamber, in accordance with an embodiment of the present disclosure.

Referring to FIG. 4A, as a general design, a plasma processing apparatus 400A includes a chamber 402A with an inner chamber wall. A workpiece support is within the inner chamber wall and is for supporting a workpiece 404A in a processing region of the chamber 402A. An upper electrode 406A is above the workpiece 404A. An ion probe 408A extends through the chamber 402A and inner chamber wall and into a plasma region above the workpiece 404A and below the upper electrode 406A. The ion probe 408A has a probe tip 409A which can be suspended over the workpiece 404A. In an embodiment, as is depicted, the ion probe 408A can extend outside of the inner chamber wall of the chamber 402A and into a slider 412 of an adaptor 410. The ion probe 408A can further extend into a quick connect coupling 414 which can include a conductive tape 416.

Referring to FIG. 4B, as a design including am ion probe with a relatively thinner section for presenting plasma disturbance, a plasma processing apparatus 400B includes a chamber 402B with an inner chamber wall. A workpiece support is within the inner chamber wall and is for supporting a workpiece 404B in a processing region of the chamber 402B. An upper electrode 406B is above the workpiece 404B. An ion probe includes a relatively thicker portion 408B1 and a relatively thinner portion 408B2. The ion probe 408B1/408B2 extends through the chamber 402B and inner chamber wall and into a plasma region above the workpiece 404B and below the upper electrode 406B. The ion probe 408B1/408B2 has a probe tip 409B which can be suspended over the workpiece 404B. In one embodiment, the relatively thinner portion 408B2 is between the relatively thicker portion 408B1 and the probe tip 409B, as is depicted.

Referring to FIG. 4C, as a design including am ion probe with a Z-neck for probing a plasma and/or sheath at various heights, a plasma processing apparatus 400C includes a chamber 402C with an inner chamber wall. A workpiece support is within the inner chamber wall and is for supporting a workpiece 404C in a processing region of the chamber 402C. An upper electrode 406C is above the workpiece 404C. An ion probe includes a base portion 408C1 and a Z-neck portion 408C2. The ion probe 408C1/408C2 extends through the chamber 402C and inner chamber wall and into a plasma region above the workpiece 404C and below the upper electrode 406C. The ion probe 408C1/408C2 has a probe tip 409C which can be suspended over the workpiece 404C. In one embodiment, the Z-neck portion 408C2 is between the base portion 408C1 and the probe tip 409C, as is depicted.

An ion probe as described herein can include one or more design features, such as a standard tip with a relatively large surface area, an internal conductive tube to form capacitive coupling with bulk plasma, an optional Z-neck to probe different plasma regions, and/or an optional tip resistor. As exemplary ion probes for including in a plasma processing region, FIGS. 4D-4E illustrate cross-sectional view of ion probes for use in a plasma processing region of a plasma processing chamber, in accordance with an embodiment of the present disclosure.

Referring to FIG. 4D, an ion probe 450 includes an outer alumina tube 451 surrounding an inner aluminum tube 452. An aluminum wire 453 extends through a portion of a center of the inner aluminum tube 452, and can be held by crimps 454. A first probe clamp 457 can be included proximate an end of the aluminum wire 453. A second probe clamp 458 can be included proximate an opposing end of the aluminum wire 453. The ion probe 450 includes a solid probe tip 460 which may be detachable, and which may be composed of aluminum, gold, or tungsten, or the like.

Referring to FIG. 4E, an ion probe 470 includes an outer alumina tube 471 surrounding an inner aluminum tube 472. An aluminum wire 473 extends through a portion of a center of the inner aluminum tube 472, and can be held by crimps 474. A first probe clam 477 can be included proximate an end of the aluminum wire 473. A second probe clamp 478 can be included proximate an opposing end of the aluminum wire 473. A probe tip resistor 479, such as a 150 k Ohm resistor, is included between the first probe clamp 477 and the second probe clamp 478. The ion probe 470 includes a solid probe tip 480 which may be detachable, and which may be composed of aluminum, gold, or tungsten, or the like.

In accordance with one or more embodiments of the present disclosure, ion probe measurements obtained using ions probes such as described in association with FIGS. 3 and 4A-4E can provide a relationship between etch rate (ER)/density uniformity and feature tilt. Relationship between center peak in measured ER maps and feature-tilt can be a center-high ion-radical density radial-profile which would result in a tilt near the center, due to sheath boundary curvature and ion trajectories distortion. However, if ER center peak is due to center-high neutral-radical density, then tilt is not expected. Global center-high radial density/ER profile (usually associated with larger gap) can produce less pronounced center-peak and feature-tilt near the center but would result in a global tilt. In an embodiment, to differentiate between the effects on ion and neutral radical density distributions (ER maps reflect both, and for tilt ions are used), ion current probe data is collected, e.g., using an ion probe such as described above.

In an embodiment, an ion probe measurement using an arrangement such as described in association with FIGS. 3 and 4A-4E is performed according to: (1) time-resolved floating potential Vf(t) is measured using a high voltage probe and scope, (2) time-average floating potential (Vf) is measured to determine the probe biasing voltage, (3) negative V with respect to the floating potential (Vf-5Te) is applied to the tip to collect ions, (4) ion current is measured at 0, 50, 100, 150, 200, and 240 mm from the wafer center, and (5) a positive V is applied to clean the tip form oxides (separate source).

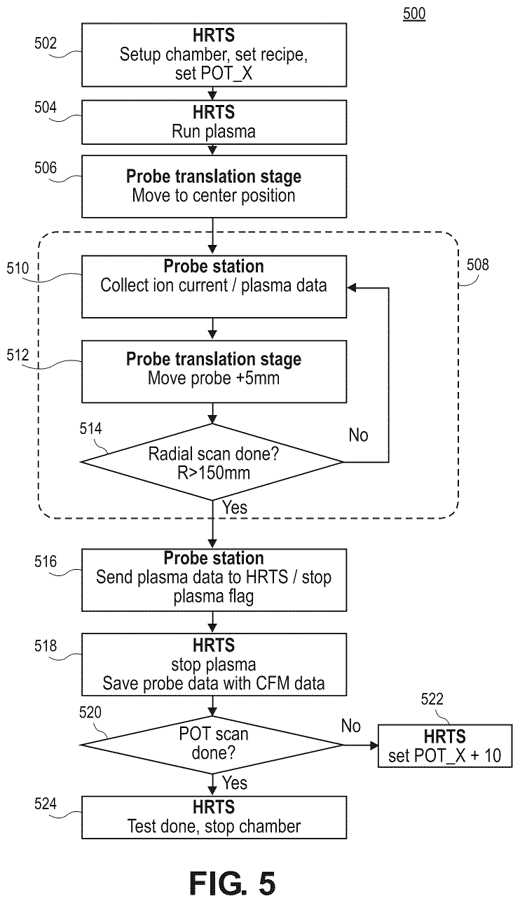

In another aspect, in accordance with one or more embodiments of the present disclosure, a plasma processing chamber is equipped with a probe station having a linear translation stage and automatic acquisition. In one such embodiment, an ion probe is used to scan and collect radial uniformity data at numerous locations by stepping the ion probe in increments using the translation stage. As an exemplary implementation, FIG. 5 is a flowchart 500 representing various operations in a method of using an ion probe to collect plasma measurements, in accordance with an embodiment of the present disclosure.

Referring to flowchart 500 of FIG. 5, at operation 502, a high resolution Thompson scattering (HRTS) measurement includes a chamber set-up with a set recipe, and with a plasma potential (POT) set at X. At operation 504, the HRTS measurement includes running the plasma. At operation 506, a probe translation stage is used to move the probe, and in particular the probe tip to a center position.

Referring again to flowchart 500, a radial scan operation 508 includes, at operation 510, using the probe station to ion current/plasma data. At operation 512, the probe translation stage is moved to move the probe tip by an increment, such as by an increment of 5 mm. A decision tree 514 is then used to determine if the radial scan is done, e.g., for a radius R of greater than 150 mm. If No, operations 510 and 512 are repeated and the decision tree 514 is determined again. If Yes, the radial scan operation 508 is complete.

Referring again to flowchart 500, at operation 516, the probe station is used to send data to an HRTS/stop plasma flag. At operation 518, the HRTS measurement involves a stop plasma operation, and saving probe data with CFM data. A decision tree 520 is then used to determine of the plasma potential scan is done. If No, at operation 522, the HRTS measurement is repeated with the plasma potential set at a factor of X+10. If Yes, at operation 524, the HRTS measurement is at final stage with the test done, and stoppage of the chamber/plasma.

In an embodiment, a workpiece processed in a plasma processing chamber can be or include any substrate that is commonly used in semiconductor manufacturing environments. For example, a workpiece may include a semiconductor wafer. In an embodiment, semiconductor materials may include, but are not limited to, silicon or III-V semiconductor materials. The semiconductor wafer may be a semiconductor-on-insulator (SOI) substrate in some embodiments. Typically, semiconductor wafers have standard dimensions, (e.g., 200 mm, 300 mm, 450 mm, or the like). However it is to be appreciated that the workpiece may have any dimension. Embodiments may also include workpieces that include non-semiconductor materials, such as glass or ceramic materials. In an embodiment, the workpiece may include circuitry or other structures manufactured using semiconductor processing equipment. In yet another embodiment, the workpiece may include a reticle or other lithography mask object.

In another aspect, an exemplary computer system of a processing tool, such as processing tool or chamber as described herein, is coupled to and controls processing in the processing tool or chamber. In an embodiment, a computer system can process ion probe measurements from ion probes such as described above. A computer system may be connected (e.g., networked) to other machines in a Local Area Network (LAN), an intranet, an extranet, or the Internet. A computer system may operate in the capacity of a server or a client machine in a client-server network environment, or as a peer machine in a peer-to-peer (or distributed) network environment. A computer system may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, the computer system may be referred to as a machine, where the term “machine” shall also be taken to include any collection of machines (e.g., computers) that individually or jointly execute a set (or multiple sets) of instructions to perform any one or more of the methodologies described herein.

A computer system may include a computer program product, or software, having a non-transitory machine-readable medium having stored thereon instructions, which may be used to program the computer system (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, a computer system includes a system processor, a main memory (e.g., read-only memory (ROM), flash memory, dynamic random access memory (DRAM) such as synchronous DRAM (SDRAM) or Rambus DRAM (RDRAM), etc.), a static memory (e.g., flash memory, static random access memory (SRAM), etc.), and a secondary memory (e.g., a data storage device), which communicate with each other via a bus.

A system processor can represent one or more general-purpose processing devices such as a microsystem processor, central processing unit, or the like. More particularly, a system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. A system processor may also be one or more special-purpose processing devices such as an application specific integrated circuit (ASIC), a field programmable gate array (FPGA), a digital signal system processor (DSP), network system processor, or the like. A system processor can be configured to execute a processing logic for performing the operations described herein.

A computer system may further include a system network interface device for communicating with other devices or machines. A computer system may also include a video display unit (e.g., a liquid crystal display (LCD), a light emitting diode display (LED), or a cathode ray tube (CRT)), an alphanumeric input device (e.g., a keyboard), a cursor control device (e.g., a mouse), and a signal generation device (e.g., a speaker).

A secondary memory may include a machine-accessible storage medium (or more specifically a computer-readable storage medium) on which is stored one or more sets of instructions (e.g., software) embodying any one or more of the methodologies or functions described herein. The software may also reside, completely or at least partially, within a main memory and/or within the system processor during execution thereof by a computer system, a main memory and a system processor also constituting machine-readable storage media. Software may further be transmitted or received over a network via a system network interface device.

While the machine-accessible storage medium may be a single medium in an exemplary embodiment, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

In the foregoing specification, specific exemplary embodiments have been described. It will be evident that various modifications may be made thereto without departing from the scope of the following claims. The specification and drawings are, accordingly, to be regarded in an illustrative sense rather than a restrictive sense.

What is claimed is:

1. An ion probe for capacitively coupling to a bulk plasma in a plasma region of a plasma processing apparatus, the ion probe comprising:
an outer alumina tube surrounding an inner aluminum tube; and
an aluminum wire extending through a portion of a center of the inner aluminum tube, the aluminum wire held by crimps.

2. The ion probe of claim 1, further comprising:
a dielectric plug with an air channel proximate an end of the aluminum wire.

3. The ion probe of claim 2, further comprising:
a probe tip proximate an opposing end of the aluminum wire.

4. The ion probe of claim 3, further comprising:
a probe tip resistor between the dielectric plug and the probe tip.

5. The ion probe of claim 4, wherein the probe tip resistor is an approximately 150 k Ohm resistor.

6. A method for monitoring a plasma parameter, the method comprising:
providing an ion probe extending through a chamber and inner chamber wall and into a plasma region of a plasma processing apparatus; and
measuring ion density, or ion energy distribution, or both ion density and ion energy distribution of a pulsed plasma in a plasma processing apparatus using the ion probe.

7. The method of claim 6, wherein the ion probe comprises an outer alumina tube surrounding an inner aluminum tube, and an aluminum wire extending through a portion of a center of the inner aluminum tube, the aluminum wire held by crimps.

8. The method of claim 7, wherein the ion probe further comprises a dielectric plug with an air channel proximate an end of the aluminum wire.

9. The method of claim 8, wherein the ion probe further comprises a probe tip proximate an opposing end of the aluminum wire.

10. The method of claim 9, wherein the ion probe further comprises a probe tip resistor between the dielectric plug and the probe tip.

11. The method of claim 10, wherein the probe tip resistor is a 150 k Ohm resistor.

12. A plasma processing apparatus, comprising:
a chamber with an inner chamber wall;
a workpiece support within the inner chamber wall, the workpiece support for supporting a workpiece in a processing region of the chamber; and
an ion probe extending through the chamber and inner chamber wall and into a plasma region above the workpiece.

13. The plasma processing apparatus of claim 12, wherein the ion probe is included in a probe station having a linear translation stage.

14. The plasma processing apparatus of claim 12, wherein the ion probe is configured to measure ion density, or ion energy distribution, or both ion density and ion energy distribution.

15. The plasma processing apparatus of claim 12, wherein the ion probe is an ion current plasma probe with a probe tip capacitively coupled to a bulk plasma in the plasma region for pulsed plasma measurements.

16. The plasma processing apparatus of claim 12, wherein the ion probe comprises an outer alumina tube surrounding an inner aluminum tube, and an aluminum wire extending through a portion of a center of the inner aluminum tube, the aluminum wire held by crimps.

17. The plasma processing apparatus of claim 16, wherein the ion probe further comprises a dielectric plug with an air channel proximate an end of the aluminum wire.

18. The plasma processing apparatus of claim 17, wherein the ion probe further comprises a probe tip proximate an opposing end of the aluminum wire.

19. The plasma processing apparatus of claim 18, wherein the ion probe further comprises a probe tip resistor between the dielectric plug and the probe tip.

20. The plasma processing apparatus of claim 19, wherein the probe tip resistor is an approximately 150 k Ohm resistor.
